(19) United States
(12) Patent Application Publication
(10) Pub. No.: US 2005/0069155 A1
(43) Pub. Date: Mar. 31, 2005

(54) Audio pre-amp and mid-band compressor circuit

(76) Inventor: Paul R. Gagon, Huntington Beach, CA (US)

Correspondence Address: JAMES F. KIRK, 16365 MARUFFA CIRCLE, HUNTINGTON BEACH, CA, 92649-2134, US

(21) Appl. No.: 10/672,004

(22) Filed: Sep. 26, 2003

(51) Int. Cl. H03F 21/00; H03G 7/00; H03G 3/10

(52) U.S. Cl. 381/120; 330/278

(57) ABSTRACT

An audio pre-amp and mid-band compressor circuit coupled to receive a program signal from a program signal source having a state-variable pre-amplifier responsive to a program input signal to provide a low range band-pass signal, a mid-range band-signal and a high range band-pass signal and for summing and scaling a low range band-pass signal, a mid-range band-signal and a high range band-pass signal providing a compensated signal. A voltage controlled amplifier circuit has a signal input terminal coupled to receive the compensated signal, and a control signal input coupled to receive at least a sample portion of the mid-range band-pass signal. The voltage controlled amplifier circuit responds to the amplitude of the sample portion of the mid-range band-pass signal to scale the compensated signal to provide a corrected output signal characterized to remain within a predetermined linear amplitude range at an output terminal.

This application provides information that relates to and extends the subject matter found in Ser. No. 08/377,903 filed Jan. 01, 1995 for “A LOW INPUT SIGNAL BANDWIDTH COMPRESSOR AND AMPLIFIER CONTROL CIRCUIT” which issued on Apr. 23, 1996 as U.S. Pat. No. 5,510,752; and, to Ser. No. 09/636,168 filed Apr. 22, 1996 for “A LOW INPUT SIGNAL BANDWIDTH COMPRESSOR AND AMPLIFIER CONTROL CIRCUIT WITH A STATE VARIABLE PRE-AMPLIFIER” which issued on Apr. 7, 1998 as U.S. Pat. No. 5,736,897; and, Ser. No. 09/444,541 filed Nov. 22, 1999 for “AN AUDIO BOOST CIRCUT”, all of which have a common inventor and assignee. Each of the applications mentioned herein are incorporated herein by reference in their entirety.

### FIELD OF THE INVENTION

This invention relates to the field of electronic amplifiers and more particularly to the field of signal conditioning circuits for signal compression and expansion such as those used in audio amplifiers for the purpose of reproducing music and delivering it to a speaker or other reproduction means.

### BACKGROUND OF THE INVENTION

The above referenced issued U.S. Pat. No. 5,736,897 shows a state-variable filter used as a pre-amplifier that receives an input program signal and processes the input program signal to provide three band-pass signals comprising a low band-pass-signal (Vlp), a mid-range band-pass signal (Vmp) and a high band-pass signal (Vhp) to respective inputs of a summing amplifier. The three signal components are then summed and output as a compensated signal at its output. The ‘897’ patent then shows the compensated signal being processed by a “compander” circuit first introduced in the above referenced U.S. Pat. No. 5,510,752. Application Ser. No. 09/444,541 referenced above shows the compensated signal at the output of the state-variable filter driving an audio boost circuit.

Audio amplifiers are used in appliances such as radios, television sets and CD players. It was noted that such applications had a tendency to process audio signals that had a large or dominant mid-range component of signal and that much less energy was being processed in the low and high frequency ranges. The mid-range signal was observed to have sufficient amplitude to drive the composite or compensated audio signal beyond the linear range of the amplifier. As the amplitude of the compensated signal exceeds the linear range of the amplifier, clipping takes place and signal components in the low and high frequency ranges, as well as signal in the mid range, were observed to be lost.

### SUMMARY OF THE INVENTION

The above-noted problems, and others, are overcome in accordance with the subject invention AUDIO PRE-AMP AND MID-BAND COMPRESSOR CIRCUIT which uses a mid-range control signal to control the gain of a compressor circuit that inversely increases or decreases the amplification of the entire compensated signal at the output of the pre-amplifier as a function of the average amplitude of the phase inverted mid-range audio signal that is being processed by the pre-amplifier.

A pre-amplifier 12 is coupled to receive the composite modulated input program signal and to provide a compensated output signal that includes harmonics generated by harmonic generator circuit 14.

### BRIEF DESCRIPTION OF THE DRAWINGS

Details of the invention, and of preferred embodiments thereof, will be further understood upon reference to the drawing, wherein:

FIG. 1 is a combined block diagram and schematic of the Audio Pre-Amp And Mid-Band Compressor Circuit,

FIG. 2 is a combined block diagram and schematic of the State-Variable Pre-Amplifier.

### DETAILED DESCRIPTION OF PREFERRED EMBODIMENTS

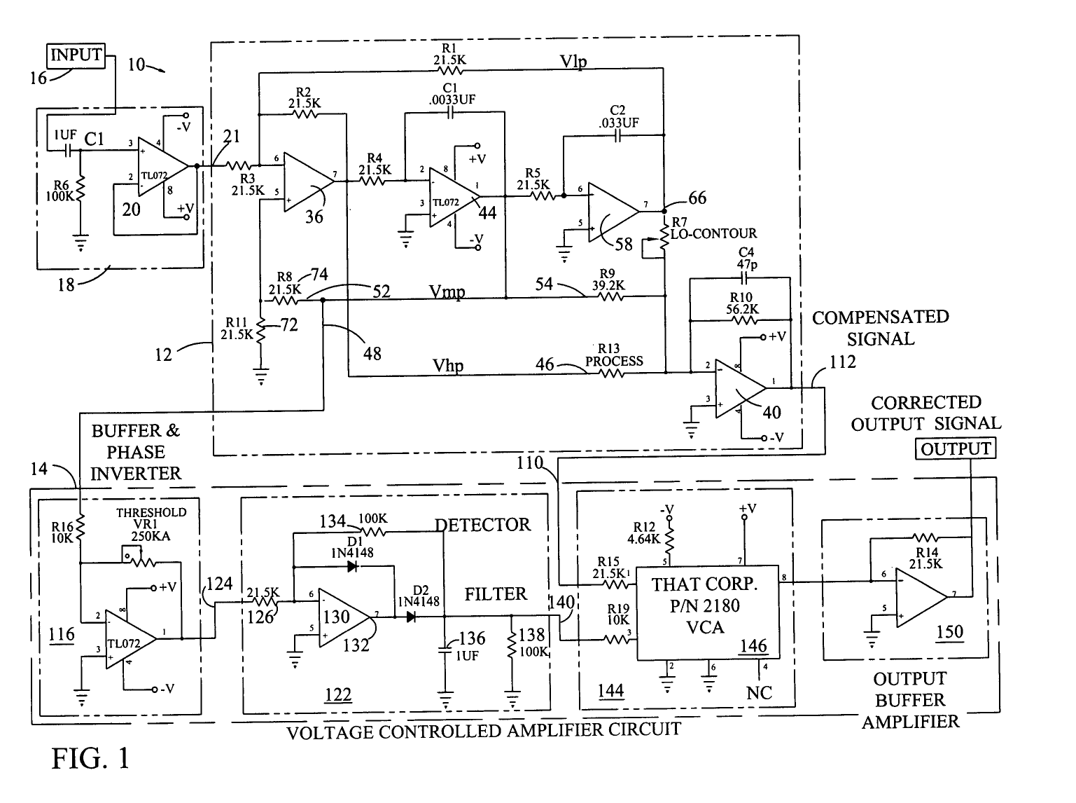

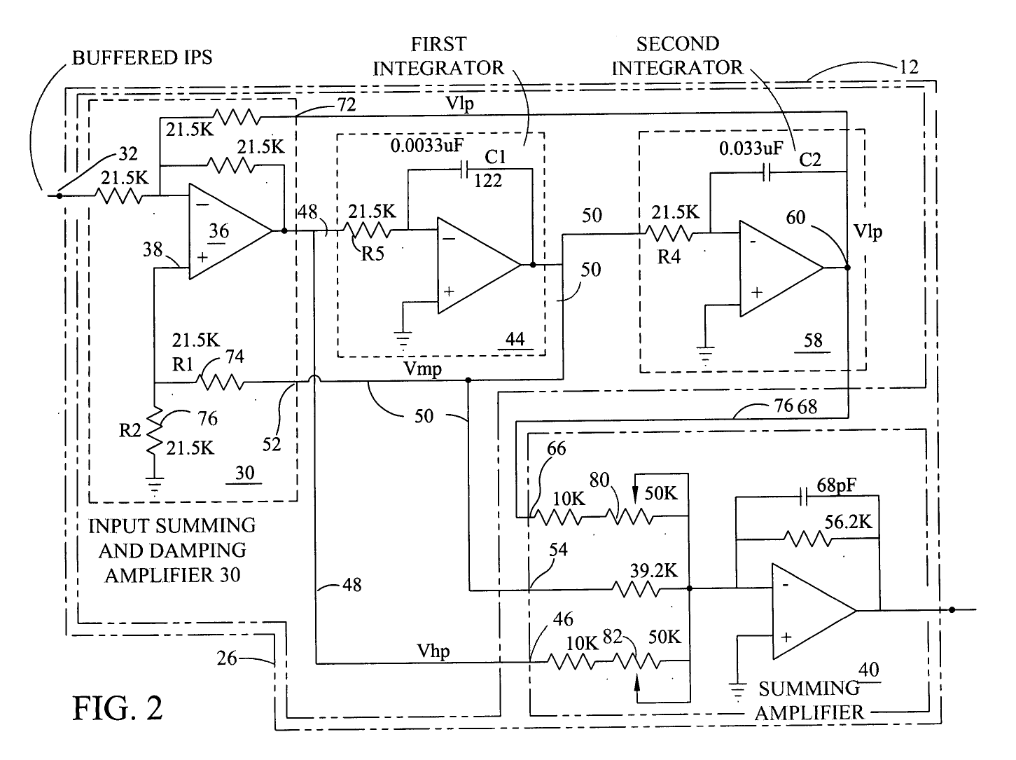

FIG. 1 shows the invention Audio Pre-Amp and Mid-Band Compressor Circuit 10 comprising an All-Pass State-Variable Filter Pre-Amp within phantom block 12 and a Mid-Band Compressor Circuit within phantom block 14. The combined block diagram and schematic of FIG. 2 provides a more easily understood depiction of the All-Pass State-Variable Filter Pre-Amp 12.

### The All-Pass State-Variable Filter Pre-Amp

Referring now to FIG. 1, the Audio Pre-Amp And Mid-Band Compressor Circuit 10 receives an IPS (input program signal) at INPUT terminal 16 from a program signal source such as a CD Player, magnetic read head or a stylus on a turntable (not shown) and couples the IPS to a Buffer Circuit within phantom block 18. Capacitor C1 within Buffer Circuit 18 removes any dc signal component from the IPS and couples the IPS to the input of a non-inverting unity gain follower circuit 20. The IPS is reproduced at the output of non-inverting unity gain follower circuit 20 without modification as a Buffered IPS. The buffered IPS is then coupled to the input 21 of the All Pass Pre-Amp 12. The All Pass Pre-Amp is a state-variable pre-amplifier that is characterized in U.S. Pat. No. 5,736,897 which issued on Apr. 7, 1998 to Paul R. Gagon and which has a common assignee. The contents of U.S. Pat. No. 5,736,897 are incorporated herein by reference in its entirety, and is relied on along with other U.S. patents mentioned herein for the following explanation.

The All Pass Pre-Amp 12 is substantially equivalent in performance to the Three Channel Crooks Circuit in U.S. Pat. No. 4,638,258 Issued Jan. 20, 1987 to Robert C. Crooks and assigned to Barcus-Berry Electronics of Huntington Beach the contents of which is also incorporated herein by reference in its entirety. However, the All Pass Pre-Amp 12 of FIGS. 1 and 2 has fewer parts than the Three Channel Crooks Circuit.

The All Pass Pre-Amp circuit 12 within an input summing and damping amplifier 30, a first integrator circuit 40, a second integrator 58 and a summing amplifier. The combination of these amplifiers, as shown in U.S. Pat. No. 5,736,897, forms the State-Variable Pre-Amplifier.

FIG. 2 re-arranges the circuitry within phantom block 12 to provide a more intuitive schematic of the state-variable pre-amplifier. Phantom block 30 represents an input summing and damping amplifier circuit. The buffered IPS is coupled to the inverting input of the amplifier at terminal 32. A mid-range band-pass signal, Vmp, is produced by the topology and is fed to the non-inverting input 52 of the input summing and damping amplifier circuit amplifier 30 for damping. The input summing and damping amplifier circuit 30 uses operational amplifier 36 for amplification. All operational amplifiers used in the embodiment of FIG. 1 and FIG. 2 are of the type TL-072 available from Texas Instrument and other suppliers. It should be understood that the selection of an operational amplifier for use in the embodiment of FIG. 2 is a design choice. The output of amplifier 36 is the high range band-pass signal Vhp. The high range band-pass signal Vhp is coupled to the negative input of a first integrator circuit within phantom block 44. The first integrator circuit 44 uses a second amplifier operational amplifier 45 for the inversion and integration of the Vhp signal. The high range band-pass signal Vhp is also coupled to the summing amplifier high pass input 46 via signal line 48.

The first integrator 44 integrates the Vhp signal to provide the mid-range band-pass signal Vmp at first integrator output 50. The mid-range bandpass signal Vmp is fed back to the damping input 52 of the input summing and damping amplifier circuit 30 and to the mid-range summing amplifier input 54 via signal line 50. The mid-range bandpass signal Vmp is also coupled to the inverting input of the second integrator circuit within block 58 which uses a third operational amplifier 59.

The second integrator within phantom block 58 responds to the mid-range bandpass signal Vmp on signal line 50 and provides a low bandpass signal Vlp at the second integrator output terminal 60. The low bandpass signal Vlp is coupled to the summing amplifier low band-pass signal input 66 via signal line 68. The low bandpass signal Vlp is also fed to the second inverting input 72 of the input summing and damping amplifier circuit 30.

The summing and damping amplifier circuit 30 within phantom block 30 of FIGS. 1 and 2 has an inverting input 52. The inverting input 52 drives a divider circuit that comprises an input resistor 74 that has a first terminal connected to receive the mid-range bandpass signal at damping input 52. A second terminal of resistor 74 is coupled to the first terminal of resistor 76 and to the non-inverting input 38 of operational amplifier 36. The second terminal of resistor 76 is coupled to a reference ground. The ratio of resistors 74 and 76 establish the “Q” of the state-variable filter. The higher the ratio of the resistors 74 to 76, the higher the Q. The Q of the State-Variable Filter Pre-Amp 12 of FIGS. 2 and 3 is typically in the range of 0.5 to 2 for audio applications.

One of the objectives of the state-variable filter is to set the phase shift and gains such that the mid-range band-pass frequency signals are about 180 degrees out of phase with the signal components in the lower frequency band and in the higher frequency band. The ratio of the damping resistors, the gains and break frequencies of the amplifiers and integrators are therefore set for a desired and pre-determined Q and bandpass.

In addition, as shown in FIG. 2, the Summing Amplifier 40 has a Low Frequency Band-Pass Gain Adjustment Pot 80, and a High Frequency Range Band-Pass Frequency Gain Adjustment Pot 82 that permit the user to make a final adjustment for a particular circuit and component configuration. The adjustable inputs to the summing amplifier 40 permit the user to obtain additional gain for the Vhp and Vlp signal.

The All Pass Pre-Amp circuit within phantom block 12 circuit of FIGS. 1 and 2 can be adjusted to obtain a total of 360 degrees of phase shift between the high frequency signal components of the buffered IPS with respect to the low frequency signal components of the IPS, in a frequency space over the range of 0 to 20,000 Hz. The high frequency components gain 360 degrees with respect to the low frequency components.

The All Pass Pre-Amp circuit within phantom block 12 also provides a time delay that is adjusted to obtain about 2.5 ms time delay at 20 Hz. The 20 Hz components are physically delayed in real time by up to 2.5 ms with respect to the High Frequency components. The design objectives for audio applications are taught and discussed further in U.S. Pat. No. 4,638,258 issued on Jan. 20, 1987 for a Reference Load Amplifier Correction System, to Robert C. Crooks.

Referring again to FIGS. 1 and 2, a reactance chart check will show that the break frequency for the first integrator 44 is about 2.24 KHz. The break frequency for the second integrator 58 is about a decade lower at 224 Hz and diminishes at three dB per octave. The Q of the circuit of FIG. 2 is approximated using equation (1) below:
Q=(R1+R2)/3R2=0.67 1.

where R1 is resistor 74 and R2 is resistor 72.

Viewing the circuit heuristically, the higher reactance of the smaller cap for mid-range bandpass amplifier, first integrator 44 clearly sets the gain of the first integrator 44 which provides an output equivalent to a midrange band-pass amplifier to higher values at lower frequencies than that of the second integrator 58 low which provides an output equivalent to a low range band-pass amplifier. It can also be seen that the first integrator 44 operates as a single pole filter. Therefore, the feed back signal Vmp to the damping resistors 74, 72 (R1,R2) that results in a controlled Q in the mid-range frequencies band.

In general, the Q of a band-pass filter is defined as the bandwidth divided by the center frequency. The design of the state-variable filter of FIG. 2 is taught in the text “The Active Filter Handbook” by Frank P. Tedeschi, pages 178-182, Tab Books Inc. of Blue Ridge Summit, Pa., 17212; however, this reference does not show the outputs being summed to form the desired unbalanced output that meets the desired requirement for audio applications.

The object of the design of the state variable pre-amp of FIGS. 1 and 2 is to have a first break frequency at approximately 240 Hz and a second at 2.24 KHz, about a decade away from the first break. The low break f_{cl} is established by equation (2):

$${f}_{c1} = \frac{1}{2 π R4C2} . \qquad 2$$

where R4 and C2 are the value of resistor R5 and capacitor C2. The mid range break f_{c} is established by equation (3):

$${f}_{c m} = \frac{1}{2 π R5C1} . \qquad 3$$

Once the Q is selected, the ratio of R1, 74 to R2, 76 can be calculated from the equation. In the case of the state variable pre-amp of FIGS. 1 and 2, a Q of 0.67 was selected by knowing what the desired gain bandwidth response curve would be from the above referenced U.S. Pat. No. 4,638,258. The circuit was modeled using a computer aided analysis program such as SPICE. The break frequencies were estimated from the information in the referenced U.S. Pat. No. 4,638,258. Initial component values were selected based on available components.

A reactance chart can be used for a quick approximation of the required remaining value once one of the values are known. The circuit shown had an initial goal of a design a center frequency at 700 Hz. At the center frequency, the gain of the circuit is about −1 dB or less than 1. The two adjustment pots, 80 and 82 permit an adjustment of the gain of the Vlp and the Vhp by about 15 dB with the values shown.

The Q was then adjusted using the pots 80 and 82 to provide the best match to the curves in the earlier patent to Crook. The Q and the break points were selected to match the response characteristic of the resulting circuit to the curves in the earlier patent to yield the same phase shifts, time delays and frequency response. The resistors 74 and 76 are set for a gain of nine but a slightly higher gain of 14 would be preferred.

The outputs Vhp, Vmp and Vlp of the state-variable filer represent three independent state variables. The procedure for adjusting the band-pass and gain as proposed appears in the above referenced text “The Active Filter Handbook” by Frank P. Tedeschi, at pages 178-182 is to set the value of C1 and C2 to be equal and to adjust the ratio of R1 and R2 to obtain the desired Q.

### The Voltage Controlled Amplifier

The voltage controlled amplifier circuit within phantom block 14 has a signal input 110 coupled to receive the compensated signal via signal line 112, and a control signal input 114 coupled to receive at least a sample portion of the mid-range band-pass signal via signal line 48, the voltage controlled amplifier of phantom block 14 has

a buffered phase inverter circuit shown within phantom block 116. As shown, the phase inverter is configured as an inverting amplifier with an adjustable gain having an adjustable range of from zero to 25. The buffered phase inverter 116 is responsive to the sample portion of the mid-range band-pass signal and provides a buffered sample portion of the mid-range band-pass signal at its output 118.

The buffered phase inverter 116 provides the buffered sample portion of the mid-range band-pass signal to a detector circuit within phantom block 122. The detector circuit shown uses a TL 072 and two one amp 1N4148 diodes shown as D1 and D2. The buffered sample portion of the mid-range band-pass signal is coupled to the detector circuit input 124. The input resistor 126 is coupled to the inverting input of the operational amplifier 130. As a value of the buffered sample portion of the mid-range band-pass signal increases above zero volts, the amplifier output 132 moves in a negative direction and the amplifier sinks all current flowing into resistor 126 maintaining the value of the voltage at the amplifier's inverting input at or very near zero volts. The amplifier output 132 moves a small amount in a negative direction to accommodate this. Diode D2 blocks current from capacitor C5.

As the voltage applied to the detector circuit input 124 moves below ground, the amplifier output 130 rises in voltage with a gain of the ratio of the resistance values of resistor 134 divided by resistor 126. A positive voltage develops on capacitor 136. The resulting circuit is a filter with a time constant formed by the parallel combination of capacitor 136, and the parallel combination of resistors 134 and 138. Node 140 is the output terminal of the filter circuit. If the capacitor 136 is eliminated, the voltage on node 140 is a detected sample portion of the mid-range band-pass signal. However, the parallel combination of the capacitor 136 and resistors 134 and 138 form a filter for filtering the detected sample portion of the mid-range band-pass signal to provide a detected and filtered sample portion of the mid-range band-pass signal at node 140.

The circuit within phantom block 144 is a voltage controlled amplifier circuit using a voltage controlled amplifier component (VCA) such as the THAT 2180) device 146 from the THAT Company of 45 Sumner Street, Milford, Mass. 01757-1656 USA Massachusetts. The VCA component or device 146 has its input coupled to the input terminal 110 to receive the compensated signal from signal line 112. As the amplitude of the detected and filtered sample portion of the mid-range band-pass signal at node 140 decreases, the gain of the VCA increases. As the gain of the VCA 2180 increases in response to a decrease in the control voltage, a larger portion of the corrected signal is allowed to pass to the output buffer amplifier within phantom block 150. The buffer amplifier 150 responds to an input from the VCA 2180 by providing a a corrected output signal at terminal 152 that is again inverted that remains within a predetermined linear amplitude range at output terminal 152. The band-pass of the VCA 2180 146 is substantially flat. The voltage controlled amplifier circuit within phantom block 14 can therefore be seen to avoid clipping and the introduction of non-linear signal features into the compensated signal at node 112

While certain specific relationships, materials and other parameters have been detailed in the above description of preferred embodiments, those can be varied, where suitable, with similar results. Other applications, variation and of the present invention will occur to those skilled in the art upon reading the present disclosure. Those variations are also intended to be included within the scope of this invention as defined in the appended claims.

1. An audio pre-amp and mid-band compressor circuit comprising:
a pre-amplifier circuit having a signal input responsive to an input program signal for processing the buffered input program signal to provide a low range band-pass signal, a mid-range band-pass signal and a high range band-pass signal and for adjusting or controlling the relative amplitude of each of the respective low, mid and high range band-pass signals and for summing the amplitude controlled band-pass signals to obtain a compensated signal,
a voltage controlled amplifier circuit having a signal input coupled to receive the compensated signal, and a control signal input coupled to receive at least a sample portion of the mid-range band-pass signal, the voltage controlled amplifier circuit being responsive to the sample portion of the mid-range band-pass signal to scale the compensated signal to provide a corrected output signal at an output terminal.

2. The audio pre-amp and mid-band compressor circuit of claim 1 further comprising:
a buffer circuit responsive to the input program signal for buffering the input program signal to provide an unmodified buffered input program signal to the pre-amplifier signal input.

3. The audio pre-amp and mid-band compressor circuit of claim 1 wherein the a voltage controlled amplifier circuit further comprises:
a buffer circuit responsive to the sample portion of the mid-range band-pass signal for buffering the sample portion of the mid-range band-pass signal to provide a buffered sample portion mid-range band-pass signal,
the voltage controlled amplifier circuit being responsive to the sample portion of the mid-range band-pass signal to scale the compensated signal to provide an output a corrected output signal.

4. The audio pre-amp and mid-band compressor circuit of claim 1 wherein the voltage controlled amplifier circuit further comprises:
a buffer circuit responsive to the sample portion of the mid-range band-pass signal for buffering the sample portion of the mid-range band-pass signal to provide a buffered sample portion mid-range band-pass signal,
a detector circuit having an input responsive to the buffered mid-range band-pass signal for providing a detected and filtered mid-range band-pass signal,
the voltage controlled amplifier circuit having a voltage controlled amplifier coupled having a control signal input coupled to be responsive to the detected and filtered mid-range band-pass signal scale the compensated signal to provide the corrected output signal.

5. The audio pre-amp and mid-band compressor circuit coupled to receive a program signal from a program signal source comprising:
a state-variable pre-amplifier responsive to a program input signal to provide a low range band-pass signal, a mid-range band-signal and a high range band-pass signal and for summing and scaling the a low range band-pass signal, a mid-range band-signal and a high range band-pass signal providing a compensated signal,
a voltage controlled amplifier circuit having a signal input coupled to receive the compensated signal, and a control signal input coupled to receive at least a sample portion of the mid-range band-pass signal, the voltage controlled amplifier circuit being responsive to the sample portion of the mid-range band-pass signal to scale the compensated signal to provide a corrected output signal characterized to remain within a predetermined linear amplitude range at an output terminal.

6. The audio pre-amp and mid-band compressor circuit of claim 5 wherein the mid-range compensated signal is inverted in phase with respect to the high-frequency compensated signal and the low-range compensated signal components.

7. The audio pre-amp and mid-band compressor circuit of claim 5 wherein the voltage controlled amplifier circuit having a signal input coupled to receive the compensated signal, and a control signal input coupled to receive at least a sample portion of the mid-range band-pass signal further comprises:
a buffered phase inverter circuit responsive to the sample portion of the mid-range band-pass signal to provide a buffered sample portion of the mid-range band-pass signal,
a detector circuit responsive to the buffered sample portion of the mid-range band-pass signal to provide a detected sample portion of the mid-range band-pass signal,
a filter for filtering the detected sample portion of the mid-range band-pass signal to provide a detected and filtered sample portion of the mid-range band-pass signal,
a voltage controlled amplifier and buffer circuit having a signal input coupled to be responsive to the compensated signal and a control signal input coupled to be responsive to the detected and filtered sample portion of the mid-range band-pass signal, the voltage control amplifier circuit being characterized to scale the amplitude of the compensated signal in response to the detected and filtered sample portion of the mid-range band-pass signal to provide a corrected output signal that remains within a predetermined linear amplitude range at an output terminal.

8. The audio pre-amp and mid-band compressor circuit of claim 5 wherein the mid-range compensated signal is inverted in phase with respect to the high-frequency compensated signal and the low-range compensated signal components.

9. The audio pre-amp and mid-band compressor circuit coupled to receive a program signal from a program signal source comprising:
a state-variable pre-amplifier responsive to a program input signal to provide a low range band-pass signal, a mid-range band-signal and a high range band-pass signal and for summing and scaling a low range band-pass signal, a mid-range band-signal and a high range band-pass signal providing a compensated signal, and
a voltage controlled amplifier circuit having a signal input coupled to receive the compensated signal, and a control signal input coupled to receive at least a sample portion of the mid-range band-pass signal, the voltage controlled amplifier further circuit comprising:
a buffered phase inverter circuit responsive to the sample portion of the mid-range band-pass signal to provide a buffered sample portion of the mid-range band-pass signal,
a detector circuit responsive to the buffered sample portion of the mid-range band-pass signal to provide a detected buffered sample portion of the mid-range band-pass signal,
a filter for filtering the detected buffered sample portion of the mid-range band-pass signal to provide a detected and filtered buffered sample portion of the mid-range band-pass signal,
a voltage controlled amplifier and buffer component (a VCA) having a signal input coupled to be responsive to the compensated signal and a control signal input coupled to be responsive to the detected and filtered buffered sample portion of the mid-range band-pass signal, the voltage control amplifier component being characterized to scale the amplitude of the compensated signal in response to the detected and filtered buffered sample portion of the mid-range band-pass signal to provide a corrected output signal that remains within a predetermined linear amplitude range at an output terminal.
